(19) United States
(12) Patent Application Publication
(10) Pub. No.: US 2006/0103382 A1
(43) Pub. Date: May 18, 2006

(54) Spin stand having hydrodynamic bearing motor and head/disc test device

(76) Inventors: Takahisa Mihara, Hyogo (JP); Eiji Ishimoto, Hyogo (JP); Takashi Kondo, Hyogo (JP)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/522,934

(22) PCT Filed: Sep. 16, 2003
(86) PCT No.: PCT/JP03/11763

§ 371 Date: Sep. 12, 2005

(30) Foreign Application Priority Data
Sep. 20, 2002 (JP) 2002-276289

(51) Int. Cl. G11B 33/06; G01R 33/00; G01R 35/00; G01M 19/00

(52) U.S. Cl. 324/262; 324/212; 324/202; 73/865.9

(57) ABSTRACT

There is provided a compact, lightweight, inexpensive head/disk test device. A spin stand is provided that supports a magnetic head to enable attaching and removal and comprises a fluid dynamic bearing motor that continues rotating even when the magnetic head is attached or removed. Alternatively, the spin stand comprises a fluid dynamic bearing motor and a detector for detecting changes in the back electromotive force or changes in the magnetic flux density generated by the rotation of the fluid dynamic bearing motor and for generating an index signal. Furthermore, the spin stand is provided with a fluid dynamic bearing motor and encloses a conductive fluid in a bearing of the fluid dynamic bearing motor and the bearing is grounded.

### BACKGROUND OF THE INVENTION

1. Field of the Invention

The present invention relates to a head/disk test device, more particularly, to a compact, lightweight, inexpensive head/disk test device.

2. Discussion of the Background Art

A magnetic head and a magnetic disk, which are main components of a hard disk drive (HDD), are inspected by a head/disk test device. A magnetic head generally refers to a magnetic reproducing element and a magnetic recording element disposed on a head slider supported by the tip of a head gimbals assembly (HGA). Hereinafter, the magnetic head and the magnetic disk are simply referred to as the head and the disk. The head/disk test device has the measurement targets of an HGA or a head stack assembly (HSA) having a plurality of HGAs and tests the characteristics of a head.

A head/disk test device primarily has a spin stand, an electrical signal measuring device, and controllers for controlling these devices. The spin stand has a disk rotating device and a head positioning device and positions the head above a disk rotating at high speed. The basic principles of this kind of spin stand are disclosed, for example, in Unexamined Japanese Patent Publication No. H6[1994]-150,269 (FIG. 2B) and Unexamined Japanese Patent Publication No. 2000-187,821 (FIG. 1, FIG. 12). Typical spin stands are the E5013B by Agilent Technologies, the RS-5220U by Canon, and the S1701B by Guzik Technical Enterprises. These products use an air bearing spindle motor in the disk rotating device and drive sources such as a ball screw, a linear motor, a servo motor, or a piezo element in the head positioning device. Furthermore, these products have a pneumatic circuit for the air bearings. The basic structure of this type of spin stand is disclosed in Laid-Open Japanese Patent Application No. 2002-518,777 (FIG. 1) and Agilent Technologies E5022A/B and E5023A Hard Disk Read/Write Test System Operation Manual, 18th Edition, Agilent Technologies, Inc., June 2001, pp. 17-33.

For example, the physical dimensions of the E5013B are a 60-cm width, a 78-cm depth, and a 102-cm height when the pneumatic circuit is included. The weight thereof is 150 kg. The other physical specifications of the spin stand are similar to the E5013A. For example, the production test of the head is conducted by using multiple head/disk test devices set up in the factory. Consequently, a stable, wide floor is needed to set up a head/disk test device in the head manufacturing factory. A single spin stand reaches a price of several million yen. HDD performance such as an increase in the memory capacity and a shortening of the seek time continues to improve. In keeping with this trend, the performance demanded in head/disk test devices continues to improve. Therefore, the update costs of the head/disk test devices also increase. On the other hand, the market price of a head, which is the measurement target devise, is very inexpensive. Consequently, a decrease in the costs accompanying the head tests is a very important issue in head manufacturing companies.

### SUMMARY OF THE INVENTION

The present invention dramatically reduces size and weight, and lowers the cost of the spin stand and the head/disk test device to solve the problems described above.

A spin stand having a disk rotation means for rotating a magnetic disk and a head moving means for supporting the magnetic head to allow attaching or removing and moving the magnetic head at least in the direction of the track width of the disk, where the head moving means is provided with a fine positioning means capable of positioning with high accuracy within a very small range of motion and a coarse positioning means for setting the very small range of motion of the fine positioning means at prescribed discrete positions.

Preferably, the coarse positioning means has one rotation mechanism and accomplish providing both the movement of the magnetic head among the discrete positions over the magnetic disk surface as well as to the outside of the magnetic disk and the prescribed skew angles to the head on the disk surface.

The above-mentioned discrete positions include a position where the magnetic head is separated from the magnetic disk in order to attach or remove the magnetic head.

The coarse positioning means comprises a drive means and a means for breaking or fixing a movable base that is driven by the drive means at the discrete positions.

The coarse positioning means comprises a drive means and a means for guiding and fixing a movable base that is driven by the drive means at the discrete positions.

The disk rotation means is disposed on one side of the magnetic disk and the positioning means is disposed on the other side of the magnetic disk, and the magnetic head is positioned on the latter side of the magnetic disk.

The magnetic head is supported directly above the positioning means.

The fine positioning means provides a piezo stage and the magnetic head is supported on the piezo stage so that the gap center of the magnetic head is adjacent to the center axis of the piezo stage.

The spin stand may also include a fine positioning means which provides a piezo stage and the object to be positioned is supported on the piezo stage so that the center of gravity of the object to be positioned on the piezo stage including the head is adjacent to the support center point of the piezo stage.

The fine positioning means provides a piezo stage and the stage position of the piezo stage when the tracks are written is a position offset from the center of the range of motion of the stage.

The spin stand preferably supports the magnetic head to enable attaching and removal, wherein a fluid dynamic bearing motor that continues the rotation even while attaching or removing the magnetic head is provided.

The spin stand may additionally include a fluid dynamic bearing motor and means for detecting changes in the back electromotive force or changes in the magnetic flux density created by the rotation of the fluid dynamic bearing motor and generating an index signal.

A spin stand having a fluid dynamic bearing motor, wherein a conductive fluid is enclosed in the bearing of the fluid dynamic bearing motor and the bearing is grounded.

The spin stand is optionally supported by helical springs provided with anti-vibration gel.

A head/disk test device having the spin stand described above.

### BRIEF DESCRIPTION OF THE DRAWINGS

FIG. 1 is a perspective view of a head/disk test device 10, which is an embodiment of the present invention.

FIG. 2 is a perspective view of a cassette 800.

FIG. 3 is a top view of a piezo stage 610 and a head slider 510.

FIG. 4 is a view showing the positional relationship between a track T on the disk 550 and a magnetic reproducing element RD and a magnetic recording element WR of the head slider 510.

FIG. 5 is a view showing the positional relationship between a track T on a disk 550, a head slider 510, and a head slider 511.

FIG. 6 is a top view of a piezo stage 610 and a head slider 510.

FIG. 7 is a view showing a coarse positioning device 700.

FIG. 8 is an enlarged view showing a part of the coarse positioning device 700.

FIG. 9 is a simplified top view of the coarse positioning device 700.

FIG. 10 is a simplified top view of the coarse positioning device 700.

FIG. 11 is a simplified top view of the coarse positioning device 700.

FIG. 12 is a simplified top view of the coarse positioning device 700.

FIG. 13 is a simplified top view of the coarse positioning device 700.

FIG. 14 is a simplified top view of a coarse positioning device 800.

FIG. 15 is a simplified top view of the coarse positioning device 800.

FIG. 16 is a simplified top view of the coarse positioning device 800.

FIG. 17 is a simplified top view of the coarse positioning device 800.

FIG. 18 is a simplified top view of the coarse positioning device 800.

FIG. 19 is a perspective view of a spin stand 1000.

### DETAILED DESCRIPTION OF THE PREFERRED EMBODIMENT

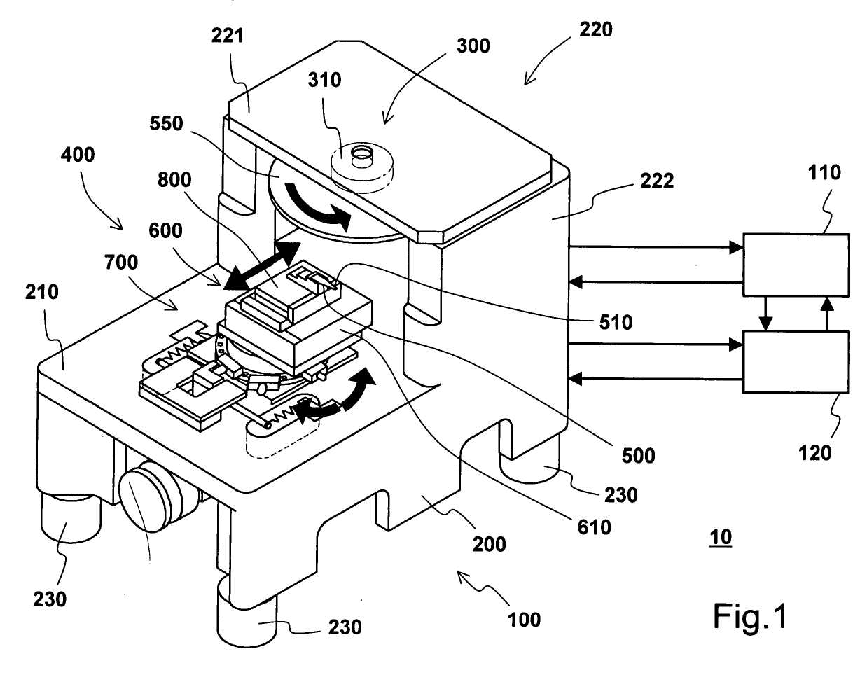

The present invention is described in detail based on embodiments of the attached drawings. An embodiment of the present invention is a head/disk test device for testing at least one of the head and the disk. In FIG. 1, the head/disk test device 10 of this embodiment comprises a spin stand 100, an electrical signal measuring device 110, and a controller 120. The electrical signal measuring device 110 is electrically connected to an HGA 500 and measures the characteristics of the head (not shown) provided in the HGA 500. The controller 120 is a device for controlling the operations of the spin stand 100 and the electrical signal measuring device 110. The spin stand 100 comprises a base 200, a disk rotating device 300, and a positioning device 400.

The base 200 is a cast aluminum base and has a planar part 210 and a bridge part 220. The bridge part 220 comprises a spindle plate 221 for supporting a suspended disk rotating device 300 and a plate post 222 perpendicular to the planar part 210 and supporting the spindle plate 221. The spindle plate 221 is screwed in to enable attaching to and removing from the plate post 222. The base 200 has legs 230 for supporting the base 200 at the four corners of the bottom surface. The legs 230 are helical springs provided with circular metal plates at both ends and are supplied with anti-vibration gel in the space inside of the helical springs. The anti-vibration gel forms a cylindrical or a rectangular shape. Both ends of the anti-vibration gel are connected to the circular metal plates similar to the helical springs. The anti-vibration gel is, for example, silicone rubber or soft estramer and has the effect of lowering the isolation frequency of the resonance frequency. Consequently, the legs 230 absorb in a wide frequency range of the extrinsic vibrations from equipment in the factory. The anti-vibration gel has a small load capacity. As will be explained later, the mass of the entire spin stand 100 is extremely light compared to a conventional spin stand and the anti-vibration gel can be applied to the spin stand 100.

The disk rotating device 300 comprises a fluid dynamic bearing motor 310 and an index signal generator IDX (not shown), and rotates the disk 550 in a fixed direction. The disk rotating device 300 can rotate the disk 550 at 4200 rpm, 5400 rpm, and 7200 rpm. Furthermore, the intermediate speeds therebetween can also be implemented with a resolution of 25 rpm. These rotation speeds and resolution are listed as examples, but do not limit the rotation speeds and resolution of the disk rotating device 300. A fluid dynamic bearing motor 310 can be more compact and lighter weight than a conventional aerostatic bearing motor while achieving the same stiffness. Consequently, the volume and the weight of the motor are about 1/40-th. The disk rotating device 300 does not stop the rotation after the disk 550 rotated momentarily because the fluid dynamic bearing motor 310 is used. A conventional head/disk test device stopped the disk rotation every time the head was replaced, that is, each time the HGA was replaced. On the other hand, the disk rotating device 300 continues to rotate the disk 550 even when the HGA 500 is attached or removed. The attaching and removing of the HGA 500 is of course replacing the HGA 500 and includes reinstalling the HGA 500. The fluid dynamic bearing motor 310 guarantees about 100,000 starts and stops. However, the demand is for the head/disk test device 10 to be capable of inspecting the HGA 500 at least 1,000,000 times annually. For example, when the fluid dynamic bearing motor 310 is started and stopped every time the HGA 500 is replaced, the lifetime of the head/disk test device 10 becomes about one month. This type of head/disk test device is unsuitable as a test device. Therefore, the head/disk test device 10 continues to rotate the disk 550 regardless of attaching or removing the HGA 500. Thus, contact with the shaft of the fluid dynamic bearing motor 310 is avoided, and the lifetime of the fluid dynamic bearing motor 310 lengthens. As a result, the fluid dynamic bearing motor 310 can be applied to the disk rotating device 300. The disk 550 rotates continuously regardless of the attachment and removal of the HGA 500, and the time needed until the fluid dynamic bearing motor 310 reaches the desired rotational speed no longer needs to be a concern. Consequently, the starting torque needed by the fluid dynamic bearing motor 310 can be designed to a small value, and the fluid dynamic bearing motor 310 is reduced in size. The fluid enclosed in the bearing of the fluid dynamic bearing motor 310 is a conductive fluid. The bearing of the fluid dynamic bearing motor 310 is grounded, and a ground conductor for grounding the rotation axis becomes unnecessary. Therefore, the disk rotating device 300 can be reduced in size and weight. Since the vibrations generated by the ground conductor disappear, the mechanical noise generated during testing also becomes small.

In contrast to the conventionally used aerostatic bearing motor, the rotation axis of the fluid dynamic bearing motor 310 only protrudes in one direction. In FIG. 1, the rotation axis (not shown) of the fluid dynamic bearing motor 310 is pointed down and supports the disk 550 on the protruding part thereof. The length of the protruding rotation axis is extremely small so that the stiffness of the axis does not decrease. Conventionally, a rotary encoder used to generate the index signal cannot be attached to a fluid dynamic bearing motor 310. The index signal used by the head/disk test device 10 does not need to correspond to the absolute angle of the rotation axis of the motor as in a HDD or a flopptical disk drive, but can accurately determine one rotation (one period) of the rotation axis of the motor. An index signal generator IDX detects the back electromotive force generated in the armature (not shown) of the fluid dynamic bearing motor 310 and generates a pulse signal. Furthermore, the index signal generator IDX generates the index signal so that one pulse is generated for each rotation of the rotation axis of the fluid dynamic bearing motor 310 by dividing the pulse signal. The pulse signal is obtained by comparing the back electromotive force signal generated in the armature (not shown) of the fluid dynamic bearing motor 310 to the signal of one phase of the armature (not shown) of the fluid dynamic bearing motor 310 in a comparator (not shown) and binarization. If an FG signal from the control circuit of the fluid dynamic bearing motor is output, the signal thereof can be used in the generation of the pulse signal. Of course, the disk and the conventional encoder can be installed external to the motor. However, the possibility of an larger spin stand is high because additional structural elements are needed.

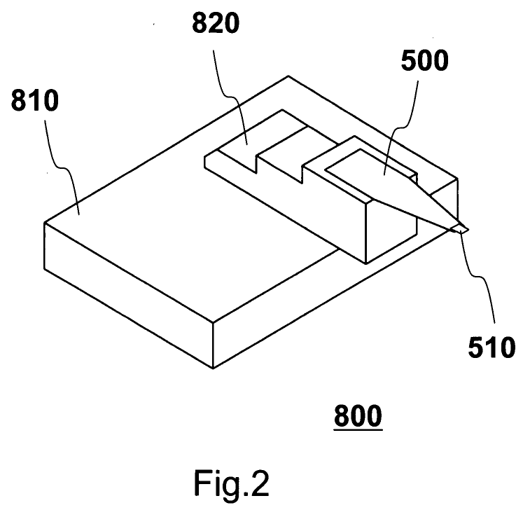

A positioning device 400 positions a head slider 510 provided on the HGA 500 at the prescribed position. The positioning device 400 comprises a fine positioning device 600 and a coarse positioning device 700. The HGA 500 is installed in a cassette 800. The cassette 800 has a structure capable of being attached to and removed from the fine positioning device 600. FIG. 2 is an enlarged view of the cassette 800. The cassette 800 comprises a cassette plate 810 and a mounting block 820 for supporting the HGA 500. The HGA 500 is supported to enable attaching to and removing from the mounting block 820.

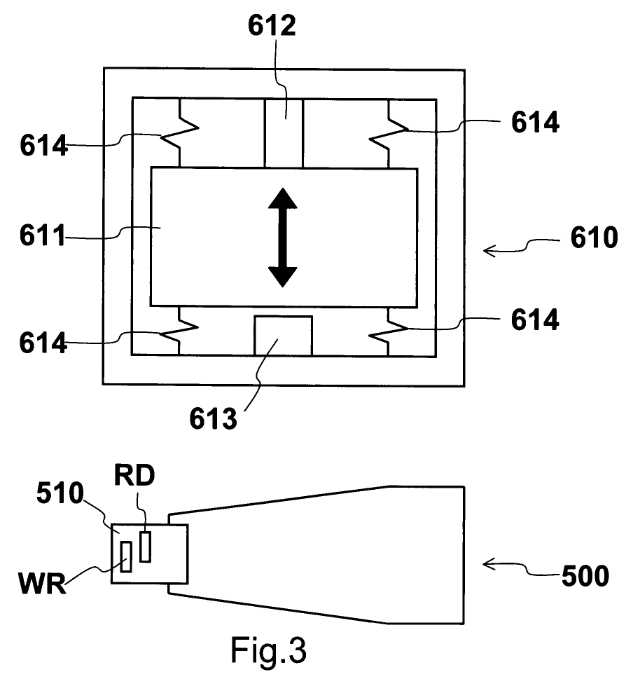

In FIG. 1, the fine positioning device 600 accurately positions the HGA 500 within the extremely small range of motion and provides a piezo stage 610. The fine positioning device 600 can position a head slider 510 on the surface of the disk 550 in the track width direction of the disk 550 (same as the radial direction of the disk 550) or a direction including the track width direction of the disk 550. FIG. 3 is a top view of the piezo stage 610 and the HGA 500. In FIG. 3, the head slider 510 provided in the HGA 500 comprises a magnetic reproducing element RD and a magnetic recording element WR. The piezo stage 610 comprises a stage 611, a piezo element 612, a capacitance sensor 613, and springs 614. The stage 611 is a movable stage and is linked to the object to be positioned such as the cassette 800. The stage 611 supports the HGA 500 by a support means, which is not shown. The cassette 800 shown in FIG. 2 is included in the support means, which is not shown. The moving direction of the stage 611 is the positioning direction of the piezo stage 610. The capacitance sensor 613 detects the amount of motion of the stage 611. The piezo element 612 is an element that is extended by an applied voltage and is the drive source for moving the stage 611. The piezo element 612 is feedback controlled based on the actual amount of the extension detected by the capacitance sensor 613.

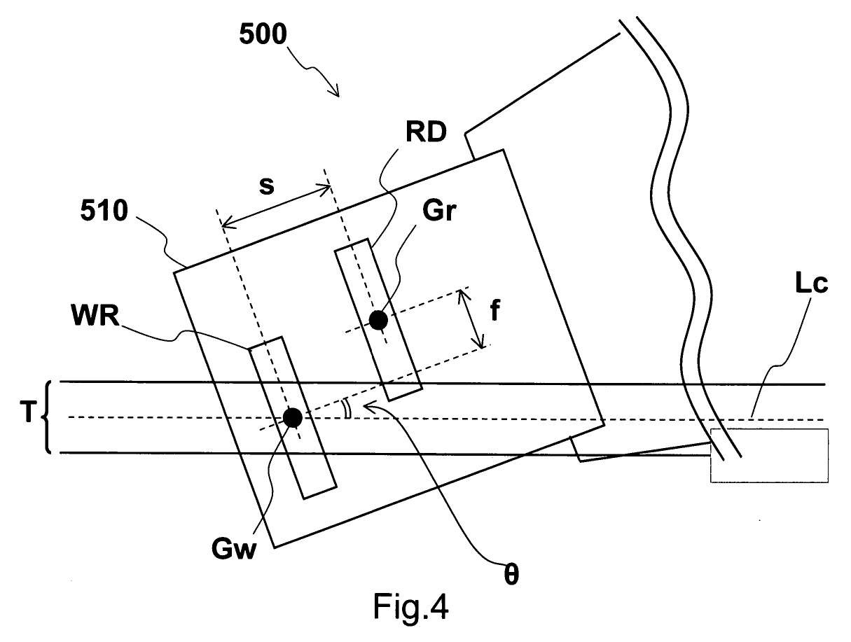

FIG. 4 shows the positional relationship between a track on the disk 400 and the magnetic reproducing element RD and the magnetic recording element WR. The gap center point Gr of the magnetic reproducing element RD needs to be positioned on the center line Lc of a track T written on the disk 550 by the magnetic recording element WR and be able to move from that position at least two tracks each in the inner circumference direction and in the outer circumference direction. When a track is written on the disk, a conventional head/disk test device positions the stage of the piezo stage at the center in the range of motion of the stage. In this case, the amount of motion of the stage of the piezo stage must be at least twice the amount of motion required in the test. On the other hand, when track T is written, the head/disk test device 10 positions the stage 611 of the piezo stage 610 at a position offset from the center position in the range of motion of the stage 611 in response to the needed amount of motion and the moving direction. Therefore, the head/disk test device 10 sets the minimum required amount of motion for the stage 611. The results are a compact piezo element 612 can be used, and the fine positioning device 600 is reduced in size.

For example, a track profile measurement is one measurement item where the effect is apparent. The track profile measurement writes the track by using the magnetic recording element of the head slider 510 to the disk 550, then the magnetic field intensity distribution of the written track is measured by the magnetic reproducing element of the head slider 510. Let the read/write offset amount of the head slider 510 be f, the read/write separation amount of the head slider 510 be s, the skew angle of the head slider 510 be θ, and the track pitch be p. The measurement range of the magnetic field intensity distribution is n tracks each in the inner circumference direction and in the outer circumference direction. The amount of motion m demanded for the stage 611 is m=m1=[(f·cos θ+s·sin θ+n·p]/cos θ) <original error> or m=m2=(2·n·p/cos θ). When (f·cos θ+s·sin θ)>(n·p/cos θ), m=m1. When (f·cos θ+s·sin θ)≦(n·p/cos θ), m=m2. Clearly from the above equations, the gap center point Gr and the gap center point Gw of the magnetic recording element WR are the same, the amount of motion m is m=(2·n·p/cos θ).

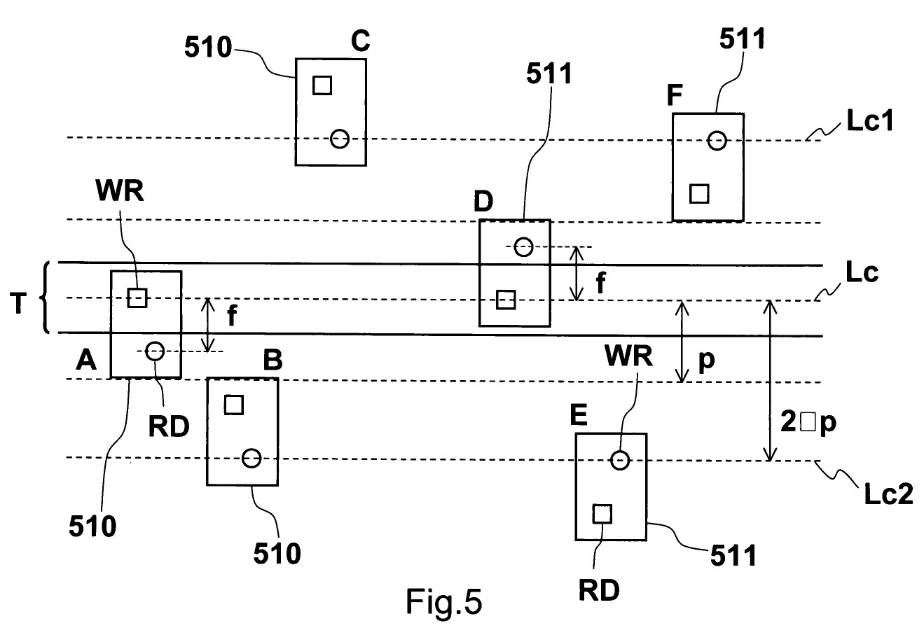

FIG. 5 shows the motion of the head slider 510 in the track profile measurement. The measurement range of the magnetic field intensity distribution is 2 tracks in the inner circumference direction and 2 tracks in the outer circumference direction. The skew angle θ is set to 0°. The head sliders 510 and the head sliders 511 shown in FIG. 5 have mirror image structures. One of head slider 510 and head slider 511 is the up-type slider head and the other is the down-type slider head. Head sliders 511 are positioned by the action of the piezo stage 610 similar to head sliders 510. A head slider 510 is positioned at the different positions A, B, and C. The head slider 510 comprises a magnetic recording element WR indicated by a square and a magnetic reproducing element RD indicated by a circle therein. Head slider 511 is positioned at the different positions D, E, and F. Similarly, the head slider 511 comprises a magnetic recording element WR indicated by a square and a magnetic reproducing element RD indicated by a circle therein. However, head slider 511 has a different arrangement of the magnetic recording element WR and the magnetic reproducing element RD than head slider 510. In head slider 510 and head slider 511, the interval between the magnetic recording element WR and the magnetic reproducing element RD, that is the read/write offset, is set to f. The track pitch is set to p. The head slider 510 writes track T by the magnetic recording element WR at position A. Then the head slider 510 measures the magnetic field intensity of the track T by using the magnetic reproducing element RD while sweeping from position B to position C. Line Lc1 and line Lc2 are at positions separated by 2 tracks (2·p) each in the inner circumference direction and the outer circumference direction from the center line Lc of track T. Head slider 511 writes track T by using the magnetic recording element WR at position D. Then head slider 511 measures the magnetic intensity of track T by using the magnetic reproducing element RD while sweeping from position E to position F. Consequently, while track T is written in the conventional manner, when the stage 611 is positioned at the center of the range of motion of the stage 611, the range of motion M of the stage 611 must be at least 2m. However, when track T is written as described above, if the stage 611 is positioned at a position offset from the center position of the range of motion of the stage 611, the range of motion M of the stage 611 can be m.

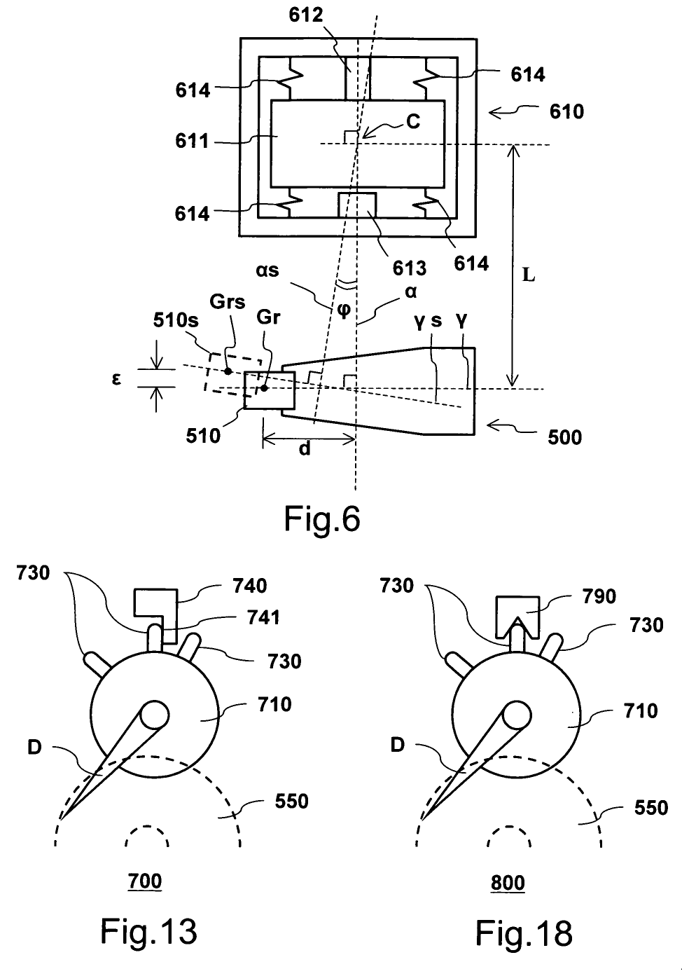

When the stage 611 is driven by the piezo element 612, the orientation thereof is tilted and moves in an inclined direction. Therefore, a positioning error is produced. The positioning error increases as the HGA 500 separates from the piezo stage 610. FIG. 6 is referred to in order to explain the positioning error of the piezo stage 610. FIG. 6 shows the HGA 500 and the head slider 510 when moved by Δ in the ideal direction by the piezo stage 610, and the head slider 510s (indicated by the dashed line) moved by Δ at an incline by the piezo stage 610. In FIG. 6, the stage 611 supports the HGA 500 by a support means, which is not shown. The cassette 800 shown in FIG. 2 is included in the support means, which is not shown. In FIG. 6, the orientation of the head slider 510s is inclined compared to the head slider 510. Point Gr is the gap center of the head slider 510. Point Grs is the gap center of the head slider 510s. Point C is the support center point of the stage 611. Point Gr and point Grs are the gap center points of the head, that is, the gap center points of the magnetic reproducing <original error> element RD of the head slider 510 or the gap center points of the magnetic recording element WR of the head slider 510. It is determined by the test specification which gap center point is that of Gr and Grs. The support center point is a point where the stage 611 can move in the ideal direction without producing a deviation when force in the ideal moving direction is applied to the support center point. Line α is a straight line extending in the ideal positioning direction of the piezo stage 610 through point C. Line α is also referred to as the center axis of the piezo stage 610. Line αs is a straight line extending in the actual positioning direction of the piezo stage 610 through point C. Line α is perpendicular to the gap center line γ that passes through the gap center point Gr. Line αs is perpendicular to the gap center line γs that passes through the gap center point Grs. At this time, the positioning error ε of the piezo stage 610 is obtained as ε=[(L+Δ)·(1−cos φ)+d·sin φ]. φ is the angle of deviation of line αs with respect to line α. L is the distance between the support center point C and the gap center line γ. L is also the distance between the support center point C and the gap center line γs. d is the distance between the gap center point Gr and the line α. d is also the distance between the gap center point Grs and the line αs. Δ is the moving distance of the stage. Since the angle of deviation φ and the amount of motion Δ are extremely small, the positioning error ε is approximated by ε=(d·sin φ). If d become small, the positioning error ε of the piezo stage 610 decreases.

As shown in FIGS. 3 and 6, HGA 500 is usually supported at a position separated from the piezo stage 610. Therefore, force is applied in a different direction than the positioning direction to the piezo stage 610. For this reason undesirable vibrations may be produced in the feedback control system of the piezo element 612. The unwanted vibrations have the negative effect on the positioning accuracy of the fine positioning device 600. Consequently, the center of gravity of the object to be positioned on the piezo stage 610 should be as close as possible to the support center point of the piezo stage 610.

The spin stand 100 of the embodiment supports the HGA 500 to be as close as possible to the piezo stage 610. Specifically, the spin stand 100 supports the HGA 500 so that the gap center point Gr of the head slider 510 is close to the center axis (line α) of the piezo stage 610 in order to decrease the distance d. The spin stand 100 supports the HGA 500 so that the center of gravity of the cassette 800 providing the HGA 500 is close to point C in order to decrease undesirable vibrations.

In a conventional spin stand, access is possible from both surface directions of the rotating disk. This type of spin stand positions two HGAs by using one positioning device. In this case, the positioning device is positioned on the outside of the disk edge and the HGA is supported at a position separated from the positioning device. If the distance between the positioning device and the HGA is long, positioning errors of the head easily occur. In FIG. 1, the spin stand 100 supports the HGA 500 directly above the fine positioning device 600 so that one HGA 500 is positioned on the lower surface of the rotating disk 550, and the excellent positioning performance is obtained.

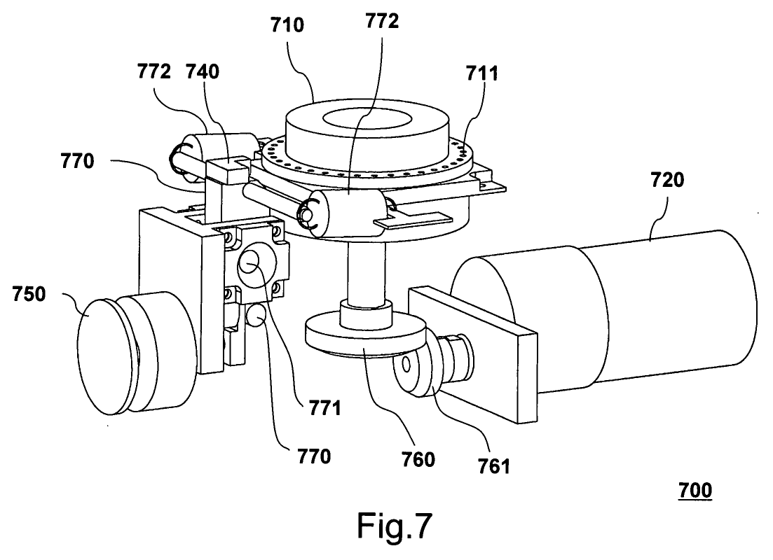

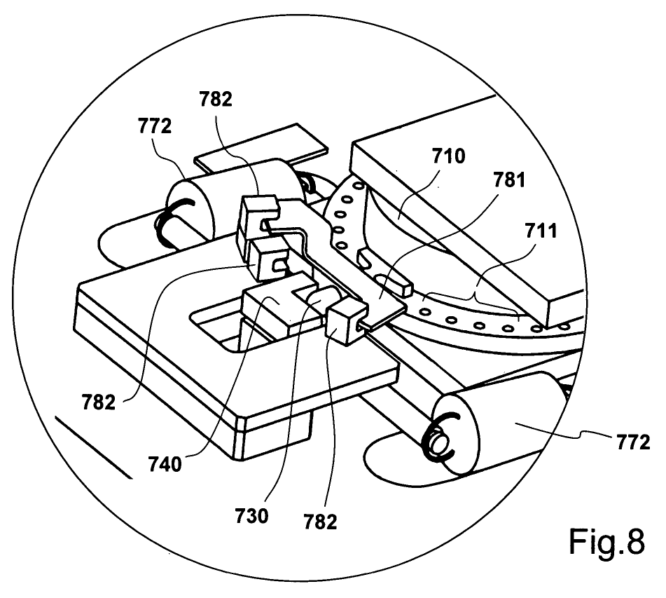

The coarse positioning device 700 shown in FIG. 1 positions the fine positioning device 600 at predetermined discrete positions. Therefore, the coarse positioning device 700 can be moved between the region above the surface of the disk 550 and outside of the disk 550 in the head slider 510 and can give the skew angle θ determined in the test specification to the head slider 510 above the surface of the disk 550. FIG. 7 shows only the coarse positioning device 700. FIG. 8 is an enlarged view of a portion of the coarse positioning device 700. The following description of the coarse positioning device 700 refers to FIGS. 7 and 8. The coarse positioning device 700 is the rotation positioning device for positioning at a predetermined angle. In this embodiment, the coarse positioning device 700 positions the fine positioning device 600 at three predetermined positions by positioning at three predetermined angles. The three predetermined positions are a position to separate the HGA 500 from the disk 550 in order to replace the HGA 500, a position to place the head slider 510 near the inner periphery above the surface of the disk 550, and a position to place the head slider 510 near the outer periphery above the surface of the disk 550. These positions are determined by the test specification, but are not limited to the above description. The coarse positioning device 700 comprises a roughly cylindrical positioning pin fixing block 710, a DC motor 720 for rotating the positioning pin fixing block 710, positioning pins 730 fixed to the positioning pin fixing block 710 and projecting in the horizontal direction, a reverse L-shaped positioning block 740, and an electromagnetic solenoid actuator 750 for horizontally moving the positioning block 740.

The positioning pin fixing block 710 is rotationally driven by the DC motor 720 via a set of gears 760. The rotational speed is about 10 rpm. The positioning pin fixing block 710 is a moving stage supporting the fine positioning device 600 and rotates both clockwise and counterclockwise. The positioning block 740 is coupled to the actuator 750 via a link 770. The link 770 is supported by a link shaft 771 and rotates with the link shaft 771 at the center. The positioning block 740 is pulled in the direction of the positioning pin fixing block 710 by the force of a spring 772. Consequently, the positioning block 740 usually is drawn in the direction of the positioning pin fixing block 710 by the force of the spring 772. When the actuator 750 presses the link 770, the positioning block 740 is separated from the positioning pin fixing block 710. Positioning pins 730 are screwed into the positioning pin fixing block 710. A set of screw holes 711 is provided to accurately change the fixing position of the positioning pins 730 in the positioning pin fixing block 710. A positioning pin 730 is a cylindrical pin and the tip thereof is hemispherical.

The coarse positioning device 700 comprises a sensor plate 781 and a photo sensor 782 fixed to the positioning pin fixing block 710 in order to control the rotation position of the positioning pin fixing block 710. The photo sensor 782 is a optical transmissive photo interrupter and detects whether or not an object that blocks light is between the light emitter and the light receiver. When a positioning pin 730 faces opposite the positioning block 740, the sensor plate 781, which is a light blocking plate, is fixed to a positioning pin fixing block 710 so that the interval between the light emitter and the light receiver of the photo sensor 782 is blocked optically. The light blocking state is effective or ineffective in response to the position of the sensor plate 781 that rotates with the positioning pin fixing block 710.

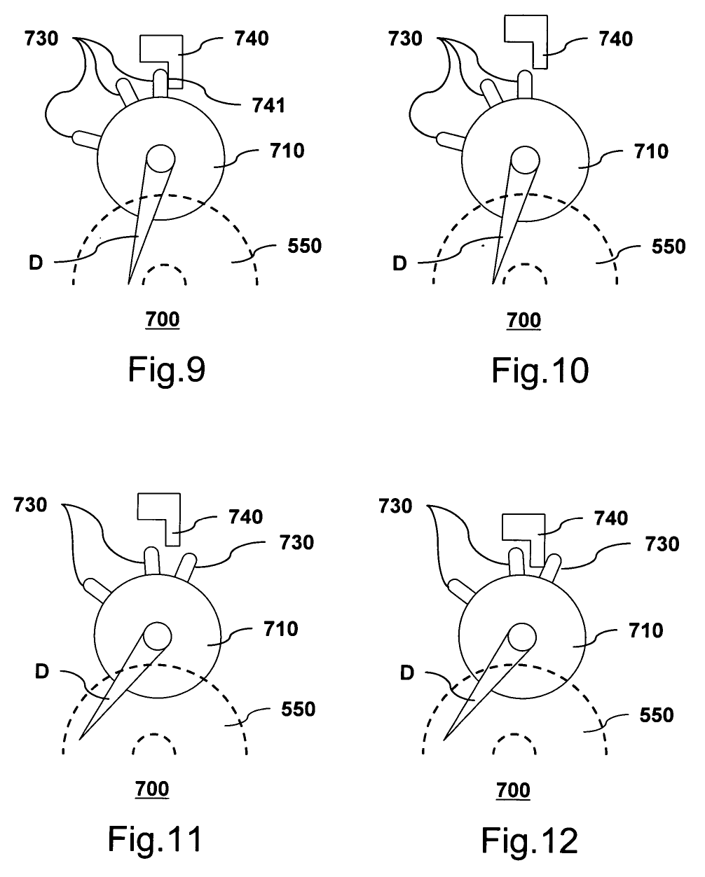

The coarse positioning device 700 positions as follows. FIGS. 9 to 13 are simplified top views of the coarse positioning device 700 and show the positioning operations thereof. The following description refers to FIGS. 7 and 8. FIG. 9 shows the coarse positioning device 700 when the magnetic reproducing element or the magnetic recording element is positioned on the inner periphery of the disk 550. In FIGS. 9 to 13, needle D (clock hand-shaped object) indicates the positioning direction of the magnetic reproducing element or the magnetic recording element. The tip of the needle D represents the position of the gap center of the magnetic reproducing element or the magnetic recording element. A positioning pin 730 is in contact with the wall surface of the positioning block 740 and remains stationary. At this time, the photo sensor 782 is blocked optically by a sensor plate 781. When the magnetic reproducing element or the magnetic recording element is positioned from the inner periphery to the outer periphery of the disk 550, first, the positioning block 740 is driven by an actuator 750 and is separated from the positioning pin fixing block 710, and the positioning pin 730 is released (FIG. 10). Next, when the DC motor 720 operates with the positioning block 740 separated from the positioning pin fixing block 710, the positioning pin fixing block 710 moves rotationally (FIG. 11). The light blocking state of the photo sensor 782 is released. The positioning pin 730 is at a position offset from the front of the positioning block 740. When the drive of the actuator 750 stops, the positioning block 740 is adjacent to the positioning pin fixing block 710 (FIG. 12). Furthermore, when the positioning pin fixing block 710 is moved rotationally, the positioning pin 730 collides with a wall surface of the positioning block 740 and brakes (FIG. 13). When the positioning pin 730 collides with the positioning block 740, the photo sensor 782 enters the light blocking state. In response to the sensor, the DC motor 720 stops. At this time, the positioning pins 730 continue to collide with the positioning block 740 for a short time due to the inertia of the DC motor 720. The position of the positioning pin fixing block 710 is fixed by electromagnetic force or a wedge. If the rigidities of the positioning pin 730 and the positioning block 740 are sufficiently high, the coarse positioning device 700 does not use an expensive highly accurate drive means or sensor means, but can achieve similar highly accurate positioning performance. The positioning block 740 for controlling the positioning pins 730 can use other means instead of the reverse L-shaped block that moves in the horizontal direction. For example, in FIG. 1, a rectangle or a cylinder that goes in and out at the planar part 210 of the base 200 as needed.

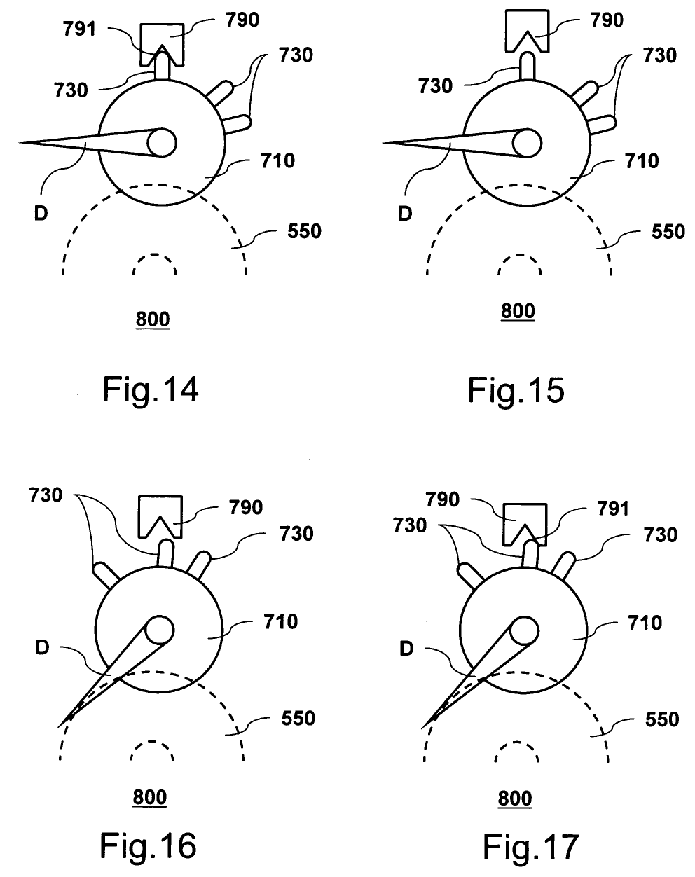

Since the positioning pins 730 can be fixed at separated positions, the positioning block 740 can have a form fixed to interpose a positioning pin 730 therebetween. For example, the coarse positioning device 800 can use a positioning block 790 having a V-shaped groove 791 instead of a positioning block 740. The positioning of the coarse positioning device 800 using the positioning block 790 is performed as follows. FIGS. 14 to 18 are simplified top views of the coarse positioning device 800 and illustrates the positioning operation thereof. The following explanation also refers to FIGS. 1, 7, and 8. FIG. 14 is a view showing the coarse positioning device 800 that positions the magnetic reproducing element or the magnetic recording element outside of the disk 550. In FIGS. 14 to 18, needle D (clock hand-shaped object) indicates the positioning direction of the magnetic reproducing element or the magnetic recording element. The tip of the needle D indicates the position of the gap center of the magnetic reproducing element or the magnetic recording element. The positioning block 790 fixes the positioning pin 730 so that the tip of the positioning pin 730 presses. At this time, the photo sensor 782 is blocked optically by the sensor plate 781. When the magnetic reproducing element or the magnetic recording element is positioned on the outer periphery of the disk from outside of the disk 550, first, the positioning block 790 is driven by the actuator 750 and is separated from the positioning pin fixing block 710, and the positioning pin 730 releases (FIG. 15). Next, when the DC motor 720 is operated with the positioning block 790 separated from the positioning pin fixing block 710, the positioning pin fixing block 710 moves rotationally (FIG. 16). Then the light blocking state of the photo sensor 782 is canceled. At this time, the positioning pin 730 is at a position offset from the front of the positioning block 790. Again, when the photo sensor 782 enters the light blocking state, the next positioning pin 730 is positioned at nearly the front of the positioning block 790. The DC motor 720 stops and the rotation motion of the positioning pin fixing block 710 stops. Furthermore, when the drive of the actuator 750 stops, the positioning block 790 is adjacent to the positioning pin fixing block 710 (FIG. 17). The coarse positioning device 800 does not use an accurate rotation position detection means, such as a rotary encoder, and the position of the positioning pin 730 is not limited to the front of the positioning block 790. The tip of the positioning pin 730 offset from the front of the positioning block 790 is guided by the inclined surface of the V-shaped groove 791 of the positioning block 790 adjacent to the positioning pin fixing block 710 and is positioned and fixed at the center of the V-shaped groove 791 (FIG. 18). The positioning pin fixing block 710 is fixed by an electromagnetic force or a wedge. As described earlier, if the rigidities of the positioning pin 730 and the positioning block 790 are sufficiently high, the coarse positioning device 800 does not use an expensive and accurate drive means and sensor means, but can implement similar accurate positioning performance.

In a test of the head slider 510, the skew angle θ of the head slider 510 positioned by the spin stand must be essentially identical to the skew angle when the head slider 510 is positioned in the actual HDD. Therefore, the spin stand 100 must set the distance between the center of the rotation axis of the disk rotating device 300 and the center of the rotation axis of the coarse positioning device 700 and the distance between the center of the rotation axis of the coarse positioning device 700 and the head slider 510 of the HGA 500 to be identical to the distances when the head slider 510 which is the test object is installed inside the actual HDD. Stated precisely, the distance between the center of the rotation axis of the coarse positioning device 700 and the head slider 510 of the HGA 500 is the distance between the center of the rotation axis of the coarse positioning device 700 and the gap center point of the magnetic recording element of the head slider 510 or the distance between the center of the rotation axis of the coarse positioning device 700 and the gap center point of the magnetic reproducing element of the head slider 510. A conventional spin stand can flexibly correspond to a similarly specified head when needed by using the positioning means driven by, for example, a linear motor to position these two distances. The type of mass-produced head to be tested does not change frequently and does not have to be positioned as described above at any time and anywhere. Instead, a spindle plate 221 has a variable fixing position to the plate post 222. The fine positioning device 600 can change the fixing position to the coarse positioning device 800. Furthermore, a mounting block 820 can change the fixing position to a cassette plate 810. And the cassette 800 can change the fixing position to the fine positioning device 600. A tester can make all of these changes. The distance between the center of the rotation axis of the disk rotating device 300 and the center of the rotation axis of the coarse positioning device 700 can be set to the same distance in the actual HDD by changing the fixing position of the spindle plate 221. By changing the fixing positions of the fine positioning device 600, the cassette 800, and the mounting block 820, the distance between the center of the rotation axis of the coarse positioning device 700 and the head slider 510 of the HGA 500 can be set to the same distance in the actual HDD.

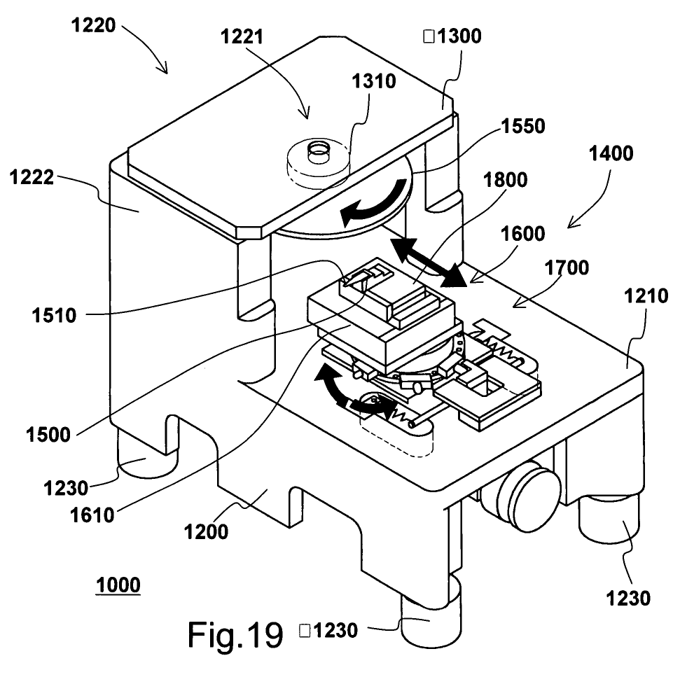

The two types of head sliders are the up-type and the down-type. An up-type head slider or an HGA having this type of head slider is referred to as an up head. A down-type head slider or an HGA having this type of head slider is referred to as a down head. The up head accesses the lower surface of a rotating disk. The down head accesses the upper surface of the same rotating disk. A conventional spin stand has a structure that tests the up head and the down head by using one spin stand. For example, some spin stands have a dual arm structure so that both the upper and lower surfaces of a disk can be accessed. Other spin stands can rotate the disk in the forward and reverse directions, and the head slider or the HGA can access both the upper and lower surfaces of the disk. One spin stand 100 of this embodiment is fixed to a rotation direction of the disk and to a disk surface accessed by the HGA. Consequently, to test both the up head and the down head, a specialized spin stand is used for each of up head and the down head. FIGS. 1 and 19 are referred to at this point. In FIG. 19, a spin stand 1000 has the same structural elements as spin stand 100. The structural elements are disposed to be the mirror image of spin stand 100. In FIG. 1 and FIG. 19, identical structural elements have the same three last digits in the reference numbers. In FIG. 1, the spin stand 100 rotates the disk 550 in the counterclockwise direction, and the HGA 500 accesses the lower surface of the disk from the right side. In FIG. 19, the spin stand 1000 rotates the disk 550 in the clockwise direction, and the HGA 500 accesses the lower surface of the disk from the left side. For example, the up head is tested by the spin stand 100, and the down head is tested by the spin stand 1000. Spin stand 100 and spin stand 1000 can be combined in only the number required for each one. The optimally combined spin stand 100 and spin stand 1000 are optimal in the mass production test.

The spin stand and head/disk test device described above, for example, can be modified as follows.

The index signal generator IDX can accurately determine one rotation (1 period) of the rotation axis of the fluid dynamic bearing motor without providing an additional device or mechanism to the rotation axis of the fluid dynamic bearing motor. Consequently, the index signal generator IDX can use a Hall element to detect the changes in the magnetic flux density generated by the permanent magnet rotating inside of the fluid dynamic bearing motor 310 to obtain the pulse signal from the fluctuations in the magnetic flux density and generate the index signal by dividing the pulse signal. Without dividing the pulse signal, the index signal can be extracted as the pulse at the prescribed position from a series of pulses appearing during one rotation of the rotation axis of the fluid dynamic bearing motor.

The rotation speed of the disk rotating device 300 can attain at least one rotation speed used in an actual HDD. The rotational speed of the disk rotating device 300 can achieve the faster 10,000 rpm or 15,000 rpm. In addition, the intermediate speeds therebetween can be achieved. It goes without saying that setting a single rotation speed makes the substantial contribution to the cost reduction of the spin stand 100. If the cost of the spin stand 100 is decreased, the cost of the head/disk test device 10 also decreases.

Furthermore, the motor used in the disk rotating device 300 can be a motor using a fluid dynamic bearing and can use an air dynamic bearing motor. In this case, the above description can be reread with the fluid dynamic bearing motor 310 replaced by the air dynamic bearing motor.

The coarse positioning device 700 can position the range of motion of the fine positioning device 600 at the discrete positions, but is not limited by the rotation positioning means with a fixed center of the rotation axis as described above. For example, the coarse positioning device 700 can be a rotation positioning means where the center of the rotation axis is not fixed.

As described in detail above, the spin stand of the present invention comprises a disk rotation means for rotating a magnetic disk and a head moving means that supports the magnetic head to enable attachment and removal and moves the aforementioned magnetic head in at least the track width direction of the disk. The head moving means comprises a fine positioning means able to accurately position in an extremely small range of motion and a coarse positioning means for setting the extremely small range of motion of the fine positioning means at prescribed discrete positions. The magnetic head can be disposed only near the above-mentioned separation positions. Consequently, the spin stand of the present invention can be smaller and lighter than a conventional spin stand.

The spin stand of the present invention can be smaller and lighter than a conventional spin stand because the rotation of a fluid dynamic bearing motor continues even when the magnetic head is attached or removed.

Furthermore, the spin stand of the present invention can be smaller and lighter than a conventional spin stand because means for detecting changes in the back electromotive force or changes in the magnetic flux density generated by the rotation of the fluid dynamic bearing motor and generating the index signal is provided.

Furthermore, the spin stand of the present invention with reduced size and weight supported by springs filled with an anti-vibration gel in the legs supporting the spin stand can be less susceptible to external vibrations than a conventional spin stand.

As a result, the spin stand of the present invention has less than 1/40-th of the volume and weight of a conventional spin stand.

1. A spin stand for supporting a magnetic head that can be attached or removed, said spin stand comprising a fluid dynamic bearing motor that continuously rotates even when the magnetic head is attached or removed.

2. A spin stand comprises a fluid dynamic bearing motor and a detector which detects changes in the reverse electromotive force or changes in the magnetic flux density caused by the rotation of the fluid dynamic bearing motor and generates an index signal.

3. A spin stand comprising a fluid dynamic bearing motor, wherein conductive fluid is enclosed in the bearing of the fluid dynamic bearing motor and the bearing is grounded.

4. The spin stand according to claim 1, wherein the spin stand is supported by helical springs provided with an anti-vibration gel.

5. A head/disk test device comprised of a spin stand for supporting a magnetic head that can be attached or removed, said spin stand comprising a fluid dynamic bearing motor that continuously rotates even when the magnetic head is attached or removed.

6. A head/disk test device comprising a spin stand comprising a fluid dynamic bearing motor and a detector which detects changes in the back electromotive force or changes in the magnetic flux density caused by the rotation of the fluid dynamic bearing motor and generates an index signal.

7. A head/disk test device comprising a spin stand comprising a fluid dynamic bearing motor, wherein conductive fluid is enclosed in the bearing of the fluid dynamic bearing motor and the bearing is grounded.
